(19) United States
(12) Patent Application Publication
(10) Pub. No.: US 2005/0212025 A1
(43) Pub. Date: Sep. 29, 2005

(54) Memory device and method of fabricating the same

(75) Inventor: Yung-Nien Teng, Taipei City (TW)

Correspondence Address: BIRCH STEWART KOLASCH & BIRCH, PO BOX 747, FALLS CHURCH, VA, 22040-0747, US

(73) Assignee: ProMOS Technologies Inc.

(21) Appl. No.: 10/962,612

(22) Filed: Oct. 13, 2004

(30) Foreign Application Priority Data
Mar. 29, 2004 (TW) 93108481

(51) Int. Cl. H01L 27/108

(52) U.S. Cl. 257/301

(57) ABSTRACT

A memory device with an array of memory cells is described. Each memory cell comprises a deep trench capacitor and an active area. The deep trench capacitor is formed in a semiconductor substrate, and includes a node electrode and a buried electrode. The active area is formed on the semiconductor substrate, electrically connecting the node electrode and a bit line. The active area substantially has an average tunnel width along a current direction of the device. The deep trench capacitor overlaps the active area, at which the active area has an intersection width larger than the average tunnel width at the boundary.

### BACKGROUND

The invention relates to a memory device and fabrication thereof, and in particular to a dynamic random access memory (DRAM) presenting faster input and output speed.

DRAM is a readable and writeable memory. As illustrated in FIG. 1, a DRAM cell consists of one transistor and one capacitor. Due to higher integrity of DRAM compared with other types of memory, DRAMs are widely applied in computers and electronic products. Currently, plane transistors with deep trench capacitors are designed to have a 3-dimensional structure, minimizing dimensions of memory cells.

FIG. 2 shows an array structure of a deep trench DRAM. In FIG. 2, a trench mask is used for defining a trench and an active area mask for defining an active area. An additional area beyond the active area and the trench acts as an isolation area. In FIG. 2, a memory cell 10 is substantially a square area comprising a trench capacitor 14 and half of an active area 12. FIG. 3 shows a three-dimensional structure with the fabricated memory cells along line 3-3′ of FIG. 2. In FIG. 3, a shallow trench isolation 20 is disposed beyond an active area 22(corresponding to the active area 12 of the mask in FIG. 2). In the memory cell, a gate 16 is formed on the active area 22. A word line W0 is disposed on the gate 16 and an additional word line W1 connects another gate 18 for controlling adjacent memory cells. Two doped regions are formed on both sides of the gate 16, one of which connects a bit line and the other connects a trench capacitor 24 (corresponding to the trench capacitor 14 of the mask in FIG. 2). The gate 16 controls the current I of the memory device.

As illustrated in FIG. 2 and FIG. 3, when reading is performed, the current I flows substantially from the trench capacitor 24 to the bit line through the underneath of the gate 16 and the active area 22. The passing width of the current I is defined by the active area 12 of the mask. The current path is one factor affecting the speed of the memory device. Hence, yield of the memory cell is reduced if the current I is too small due to faulty fabrication.

### SUMMARY

It is one object of the invention to provide a device with fluent current therein, which increases operational speed of memory cells. Additionally, yield of the resultant device is raised.

Embodiments of the invention provide an array structure of a memory device. The memory device comprises a deep trench capacitor, an active area, and a gate. The deep trench capacitor is formed in a semiconductor substrate, and comprises a node electrode and a buried electrode. The active area is formed on the semiconductor substrate, electrically connecting the node electrode and a bit line. The active area substantially comprises an average tunnel width along a current direction of a device. The boundary of the deep trench capacitor overlaps the active area Such that the active area has an intersection width at the boundary, in which the intersection width is larger than the average tunnel width. The gate is formed on the active area for controlling the current flow of the device. The memory device achieved by some embodiments of the invention has higher device current and fabrication yield.

Embodiments of the invention further provide a mask for defining a plurality of active areas of a memory device. The memory device comprises a plurality of memory cells, and each cell comprises a trench capacitor comprising a node electrode and a buried electrode disposed on a substrate. The mask comprises a plurality of active area definition regions for defining the active areas of the memory device. One active area corresponding to one memory cell connects the node electrode and a bit line, and intersects the trench capacitor at one side, resulting in an intersection width. The active areas substantially have an average tunnel width along a current direction of the memory device. The intersection width is larger than the average tunnel width.

Embodiments of the invention additionally provide a method for fabricating a memory device. A trench capacitor comprising a node electrode and a buried electrode is formed on a substrate. An active area substantially comprising an average tunnel width along a current direction of the memory device is defined on the substrate by a mask. The active area electrically connects the node electrode and a bit line, and intersects the trench capacitor at one side, and hence has an intersection width, in which the intersection width is larger than the average tunnel width. A gate is formed on the active area for controlling the current flow of the device.

Because the intersection width is larger than the average tunnel width, the resistance of the overlap between the capacitor and the active area is relatively reduced. As a result, the current of the device passing through the overlap in accordance with the invention is higher, leading to higher operational speed.

Furthermore, the process window of photolithography is increased due to larger intersection width. Therefore, yield of resultant device is less influenced by misalignment issue in photolithography.

### DESCRIPTION OF THE DRAWINGS

The invention can be more fully understood by reading the subsequent detailed description and examples with references made to the accompanying drawings, wherein:

FIG. 1 shows an equivalent circuit diagram of a conventional deep trench DRAM.

FIG. 2 shows an array structure of a conventional deep trench DRAM.

FIG. 3 shows a three-dimensional structure along line 3-3′ of FIG. 2 with fabricated memory cells.

FIG. 4 illustrates an array structure of a deep trench DRAM according to an embodiment of the invention.

FIG. 5 shows a three-dimensional structure along line 5-5′ of FIG. 4 with fabricated memory cells.

FIG. 6 shows an equivalent circuit diagram of a memory cell in FIG. 4 and FIG. 5.

FIG. 7A illustrates an array structure of a deep trench DRAM according to another embodiment of the invention.

FIG. 7B illustrates an array structure of a deep trench DRAM according to yet another embodiment of the invention.

FIG. 8 is a flow chart of an embodiment of the invention.

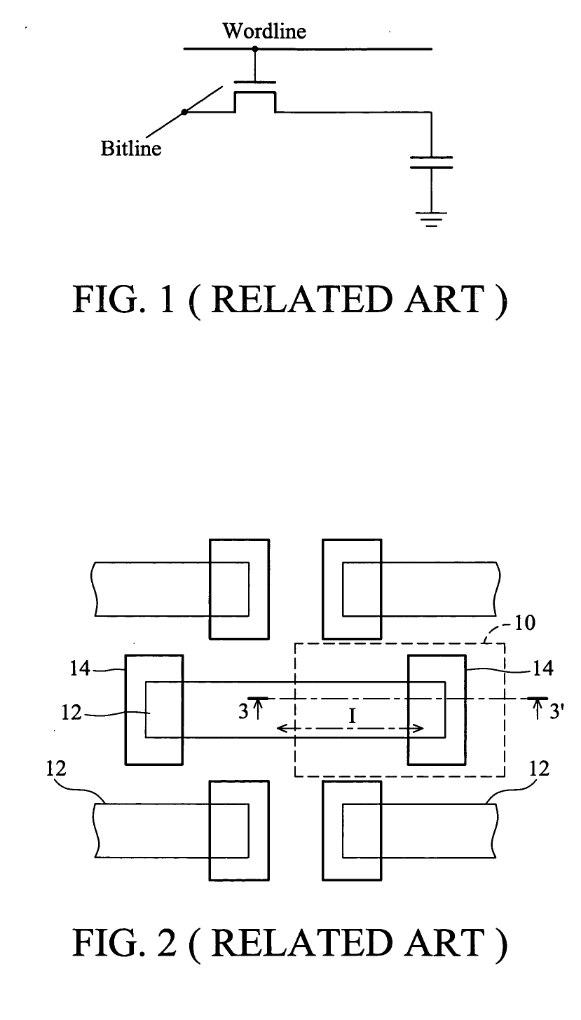

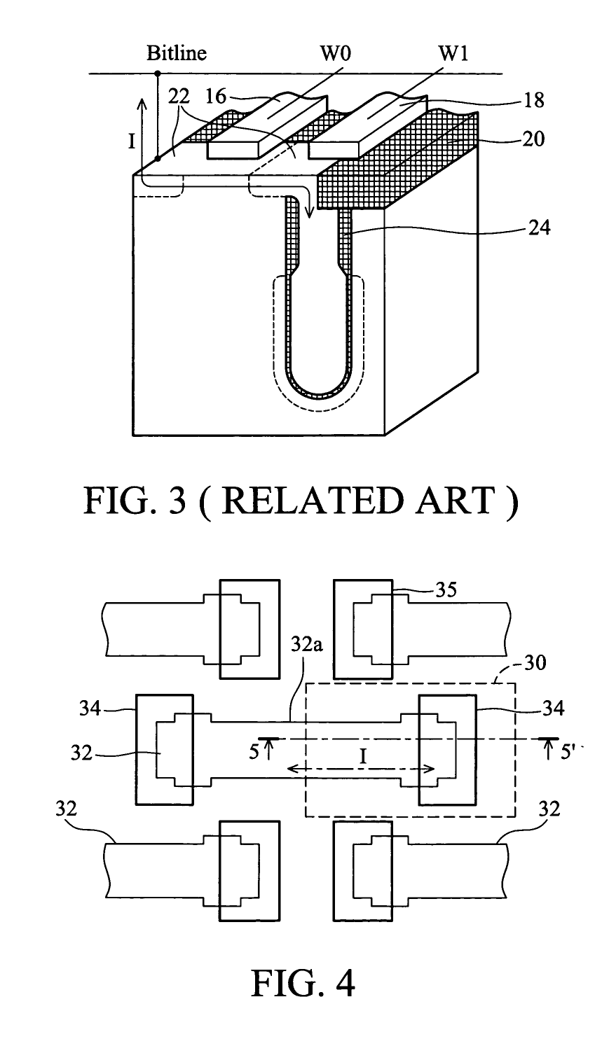

### DETAILED DESCRIPTION

Embodiments of the invention provide an active area mask with enlarged width at the intersection of an active area and a trench capacitor for increasing memory device current.

FIG. 4 illustrates an array structure of a deep trench DRAM according to an embodiment of the invention. In FIG. 4, a trench mask is used for defining a trench capacitor 34 and an active area mask for defining an active area 32. The active area 32 is an area provided for subsequent formation of a transistor. An additional area beyond the active area 32 and the trench capacitor 34 acts as an isolation area. In FIG. 4, a memory cell 30 is substantially a square area comprising the trench capacitor 34 and half of the active area 32. In other words, an active area 32 is shared by two mirror cells 30. For convenience, the active area 32 hereinafter refers to the active area of a memory cell.

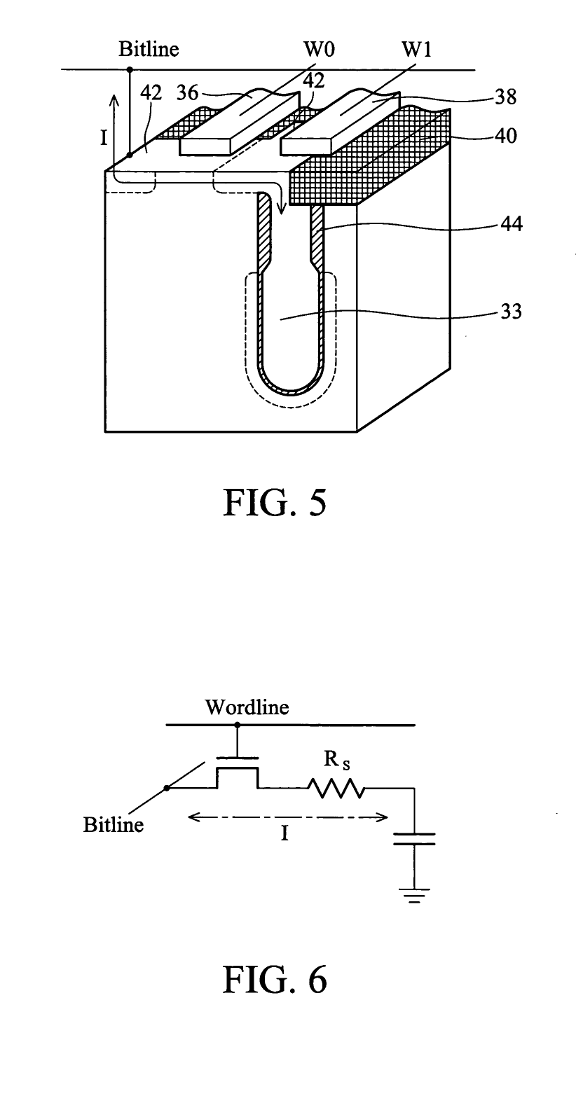

FIG. 5 shows a three-dimensional structure along line 5-5′ of FIG. 4 with fabricated memory cells. In FIG. 5, a shallow trench isolation 40 is formed beyond the active area 42 (corresponding to the active area 32 of the mask in FIG. 4). In the memory cell, a word line W0 is placed on a gate 36, and an additional word line W1 connects another gate 38 controlling adjacent memory cells. Two doped regions are formed on both sides of the gate 36, one of which connects a bit line and the other connects a trench capacitor 44 (corresponding to the trench capacitor 34 of the mask in FIG. 4). The gate 36 controls the current I of the memory device when reading/writing of the device is performed. Additionally, the active area 32a is a current path between the node electrode 33 of the trench capacitor 44 (corresponding to the trench capacitor 34 in FIG. 4) and the bit line. The current I flows in a direction shown in FIG. 4 and FIG. 5.

As illustrated in FIG. 4 and FIG. 5, each active area 32a is substantially a strip with a constant width, and an enlarged width at the intersection of the active area 32a and the trench capacitor 34. In this embodiment, the active area 32a in the memory cell 30 is cross-shaped. The constant width is defined as an average tunnel width, and the enlarged width is subsequently defined as the intersection width. As shown in FIG. 4 and FIG. 5, the intersection width is larger than the average tunnel width.

FIG. 6 shows an equivalent circuit diagram of a memory cell in FIG. 4 and FIG. 5, where Rₛ refers to the equivalent resistance between the gate 36 and the trench capacitor 44, and I refers to the current flowing therebetween. The current is inversely proportional to the resistance under the same applied voltage. That is, the current is increased if the Rₛ is reduced. Since Rₛ is reduced when enlarging the intersection width, the memory device current is effectively increased.

Furthermore, misalignment is likely to occur during semiconductor fabrication. The active area 12 shown in FIG. 2 is easily formed as oval-shaped due to the proximity effect or corner rounding. Consequently, when misalignment occurs, the width of the intersection between the active area 12 and the trench capacitor 14 is reduced, thus increasing the resistance thereof and reducing the device current, and yield is further reduced. The enlarged intersection width in the overlap between the active area 32 and the trench capacitor 34 of FIG. 4 according to the embodiments of the invention, however, can effectively eliminate the described problem.

The active area 32a with enlarged intersection width cannot be so close to an additional trench capacitor, that leakage may be generated. Accordingly, the intersection width is limited. The preferable ratio of the intersection width to the average tunnel width is around 1.1˜2.5.

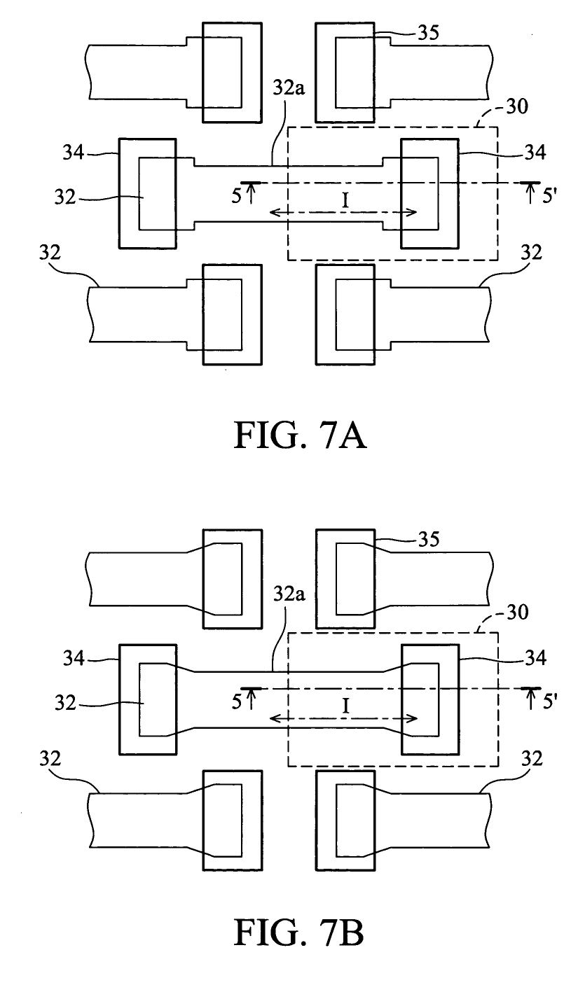

The shape of the active area 32 mask is not limited to the cross-shape. It can be any shape with an intersection width larger than the average tunnel width. For example, as illustrated in FIG. 7A, the active area 32 mask can be T-shaped, or as illustrated in FIG. 7B, the active area 32 mask can be funnel-shaped.

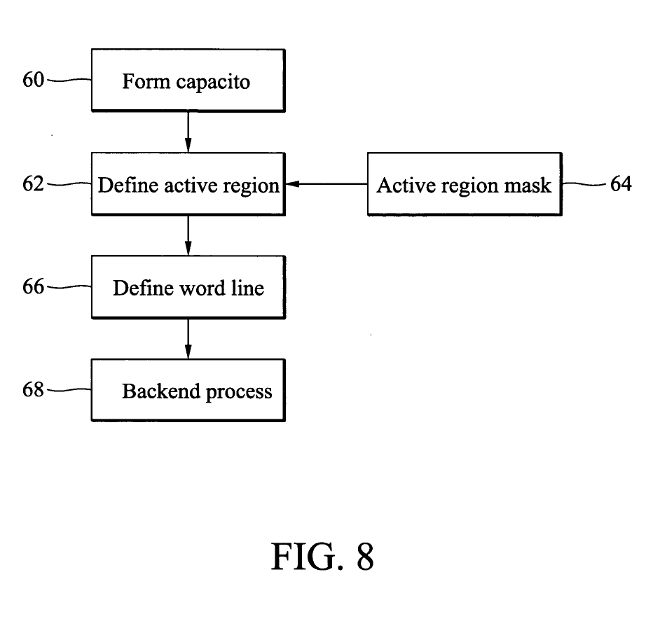

FIG. 8 is a flow chart of an embodiment of the invention. Referring to FIG. 8, a trench capacitor is formed in a substrate in step 60. An active area mask with an intersection width larger than an average tunnel width is provided in step 64. In step 62, an active area is defined on the substrate using the active area mask of some embodiments of the invention. A gate (word line) is formed in step 66, and back end processes, for example, forming bit lines and interconnects, are subsequently performed in step 68.

Embodiments of the invention provide larger device current than conventional technology. Therefore, yield of the resultant device is raised. Moreover, a larger process window for photolithography is provided, and the problem in small current caused by misalignment is thus eliminated.

While the invention has been described by way of example and in terms of preferred embodiment, it is to be understood that the invention is not limited to the disclosed embodiments. To the contrary, it is intended to cover various modifications and similar arrangements (as would be apparent to those skilled in the art). Therefore, the scope of thee appended claims should be accorded the broadest interpretation so as to encompass all such modifications and similar arrangements.

1. A memory device, comprising a plurality of memory cells arranged in an array, each of the cells comprising:
a trench capacitor disposed on a substrate, wherein the trench capacitor comprises a node electrode and a buried electrode;
an active area substantially comprising an average tunnel width along a current direction of the memory device disposed on the substrate, wherein the active area electrically connects the node electrode and a bit line, and intersects the trench capacitor at one side with an intersection width at the intersection, wherein the intersection width is larger than the average tunnel width; and
a gate disposed on the active area for controlling current flow of the memory device.

2. The memory device as claimed in claim 1, wherein a ratio of the intersection width to the average tunnel width is about 1.1˜2.5.

3. The memory device as claimed in claim 1, wherein the active area is cross-shaped, T-shaped or funnel-shaped.

4. A mask for defining a plurality of active areas of a memory device, the memory device comprises a plurality of memory cells, and each cell comprises a trench capacitor comprising a node electrode and a buried electrode disposed on a substrate, the mask comprising:
a plurality of active area definition regions for defining the active areas of the memory device, wherein at least one of the active areas corresponding to one of the memory cells connects the node electrode and a bit line, and intersects with the trench capacitor at one side to have an intersection width at the intersection, wherein the active areas substantially have an average tunnel width along a current direction of the memory device, and the intersection width is larger than the average tunnel width.

5. The mask as claimed in claim 4, wherein a ratio of the intersection width to the average tunnel width is about 1.1˜2.5.

6. The mask as claimed in claim 4, wherein the active areas are cross-shaped, T-shaped or funnel-shaped.

7. A method for fabricating a memory device, comprising:
forming a trench capacitor on a substrate, wherein the trench capacitor comprises a node electrode and a buried electrode;
defining an active area on the substrate utilizing a mask, wherein the active area has an average tunnel width along a current direction of the memory device, electrically connects the node electrode and a bit line, and intersects the trench capacitor at one side to have an intersection width at the intersection, wherein the intersection width is larger than the average tunnel width; and
forming a gate on the active area to control current flow of the memory device.

8. The method as claimed in claim 7, wherein a ratio of the intersection width to the average tunnel width is about 1.1˜2.5.

9. The method as claimed in claim 7, wherein the active area is cross-shaped, T-shaped or funnel-shaped.
